(19) United States
(12) Patent Application Publication
(10) Pub. No.: US 2025/0227971 A1
(43) Pub. Date: Jul. 10, 2025

(54) QUANTUM DOT, ELECTRONIC DEVICE, AND METHOD OF PREPARING QUANTUM DOT

(71) Applicants: SAMSUNG ELECTRONICS CO., LTD., Suwon-si (KR); Research & Business Foundation SUNGKYUNKWAN UNIVERSITY, Suwon-si (KR)

(72) Inventors: Moon Gyu HAN, Suwon-si (KR); Sohee Jeong, Suwon-si (KR); Meeree Kim, Suwon-si (KR); Heejae Lee, Suwon-si (KR); Shin Ae Jun, Suwon-si (KR); Seung Hwa Hong, Suwon-si (KR)

(21) Appl. No.: 19/013,497

(22) Filed: Jan. 8, 2025

(30) Foreign Application Priority Data
Jan. 8, 2024 (KR) 10-2024-0003183

(51) Int. Cl. H10D 62/81; C09K 11/02; C09K 11/74; H10D 62/00; H10D 62/10; H10D 62/85

(52) U.S. Cl. CPC H10D 62/81; C09K 11/025; C09K 11/7492; H10D 62/01; H10D 62/118; H10D 62/85

(57) ABSTRACT

A quantum dot including a Group IIIA element and a Group VA element of the periodic table of elements, wherein the quantum dot has an absorption peak wavelength of greater than or equal to about 1,000 nm in a visible-infrared (Vis-IR) absorption spectrum, and includes a ligand derived from an aliphatic hydrocarbon compound substituted with a hydroxyl group (—OH) and a thiol group (—SH) on its surface, a method for preparing the quantum dot, and an electronic device including the quantum dot.

### CROSS-REFERENCE TO RELATED APPLICATION

This application is based on and claims priority to Korean Patent Application No. 10-2024-0003183 filed in the Korean Intellectual Property Office on Jan. 8, 2024, and all the benefits accruing therefrom under 35 U.S.C. § 119, the content of which is herein incorporated by reference in its entirety.

### BACKGROUND

### 1. Field

Quantum dots, electronic devices, and methods for preparing quantum dots are disclosed.

### 2. Description of the Related Art

Physical properties such as energy bandgaps and melting points, which are intrinsic to nanoparticles, may be controlled by changing their particle sizes, unlike bulk materials. Semiconductor nanocrystals, also known as quantum dots (QDs), are semiconductor materials with a crystal structure of several nanometers in size. Due to their very small size, these semiconductor nanocrystals have a large surface area per unit volume and exhibit quantum confinement effects. Therefore, they may exhibit different physicochemical characteristics compared to bulk materials. For example, quantum dots may have their energy bandgaps adjusted based on their size and composition, allowing them to absorb light across various wavelengths or emit light at specific wavelengths. Accordingly, interest in quantum dots is high as they may be applied in various fields such as displays, energy, electronics, and biotechnology.

Quantum dots based on cadmium (Cd), lead (Pb), or mercury (Hg) are known to exhibit enhanced optical properties. However, all of these are toxic heavy metal elements that can pose a serious threat to the environment. Therefore, there is a need for the development of quantum dots that have excellent properties of absorbing or emitting light in a specific region and a method for preparing the same, without including such toxic heavy metal elements.

### SUMMARY

An embodiment provides quantum dots capable of absorbing light in the near-infrared region without including environmentally harmful heavy metals.

Another embodiment provides a method for preparing the quantum dots.

Another embodiment provides an electronic device including the quantum dots.

A quantum dot according to an embodiment includes a Group IIIA element and a Group VA element of the periodic table of elements and has an absorption peak wavelength of greater than or equal to about 1,000 nanometers (nm) in a visible-infrared (Vis-IR) absorption spectrum, and includes a ligand derived from an aliphatic hydrocarbon compound substituted with a hydroxyl group (—OH) and a thiol group (—SH) on a surface of the quantum dot.

The quantum dot may not include mercury, cadmium, lead, or a combination thereof.

The quantum dot may have an average particle size of greater than or equal to about 2.5 nm.

The Group IIIA element may include indium (In), aluminum (AI), gallium (Ga), or a combination thereof.

The Group VA element may include arsenic (As), antimony (Sb), bismuth (Bi), or a combination thereof.

The ligand may be derived from a linear or branched aliphatic hydrocarbon compound having 2 to 30 carbon atoms substituted with one or more hydroxyl groups and one or more thiol groups.

The aliphatic hydrocarbon compound substituted with a hydroxyl group (—OH) and a thiol group (—SH) may include 1-hydroxy-2-mercapto ethane (ME), 1,2-dihydroxy-3-mercapto propane (MPD), or a combination thereof.

The absorption peak wavelength of the quantum dot may be in a range of about 1,000 nm to about 1,800 nm.

The quantum dot may include indium (In) and arsenic (As).

A molar ratio of the Group VA element to the Group IIIA element in the quantum dot is greater than or equal to about 0.5:1 and less than or equal to about 1:1.

An electronic device according to another embodiment includes a first electrode and a second electrode spaced apart from each other; and a semiconductor layer including the aforementioned quantum dot between the first electrode and the second electrode.

The first electrode and the second electrode may have main surfaces facing each other, and the semiconductor layer may be interposed between the first electrode and the second electrode.

The electronic device may include a charge auxiliary layer between the semiconductor layer and the first electrode, between the semiconductor layer and the second electrode, or both.

The electronic device may further include a third electrode facing the semiconductor layer; and an insulating layer between the semiconductor layer and the third electrode.

The electronic device may have a field effect mobility of greater than or equal to about 10-5 square centimeters per vol-second (cm²/ Vs).

The electronic device may have an external quantum efficiency (EQE) of greater than or equal to about 10%.

A method for preparing a quantum dot according to another embodiment includes:
preparing a precursor solution of a Group IIIA element including a precursor of a Group IIIA element, a first amine compound, and optionally a phosphine compound;
preparing a precursor solution of a Group VA element including a precursor of a Group VA element and a second amine compound;
while heating the precursor solution of the Group IIIA element, mixing the precursor solution of the Group VA element with the precursor solution of the Group IIIA element and reacting the precursor of the Group IIIA element and the precursor of the Group VA element;
after the reacting, obtaining a quantum dot including the Group IIIA element and the Group VA element, and including the first amine compound, the second amine compound, the optional phosphine compound, or a combination thereof on a surface of the quantum dot; and
replacing the first amine compound, the second amine compound, the phosphine compound, or the combination thereof on the surface of the obtained quantum dot with an aliphatic hydrocarbon compound substituted with a hydroxy group (—OH) and a thiol group (—SH), wherein the quantum dot includes the Group IIIA element and the Group VA element, and has an absorption peak wavelength of greater than or equal to about 1,000 nanometers in a visible-infrared absorption spectrum.

The precursor of the Group IIIA element and the precursor of the Group VA element may include a halide, a sulfide, an amine-containing compound of the Group IIIA element and the Group VA element, or a combination thereof.

The first amine compound and the second amine compound may be the same as or different from each other, and each independently may include RNH₂, R₂NH, or a combination thereof wherein R each independently represents a C5 to C40 substituted or unsubstituted aliphatic hydrocarbon group, a C6 to C40 substituted or unsubstituted aromatic hydrocarbon group, or a combination thereof.

The phosphine compound may be present, and may include R₃PO, R₂HPO, RH₂PO, R₃P, R₂PH, RPH₂, RPO(OH)₂, RHPOOH, R₂POOH, or a combination thereof (wherein R each independently represents a C5 to C40 substituted or unsubstituted aliphatic hydrocarbon group, a C6 to C40 substituted or unsubstituted aromatic hydrocarbon group, or a combination thereof).

The quantum dot according to an embodiment may exhibit improved optical properties, for example, absorbing light in a long wavelength region of greater than or equal to about 1,000 nm, and also improved electrical properties, for example, high charge mobility, without including toxic heavy metal elements, such as cadmium, lead, mercury, or a combination thereof. Accordingly, the quantum dot can be applied to a semiconductor film in devices such as photodiodes, photodetectors, and field-effect transistors.

### BRIEF DESCRIPTION OF THE DRAWINGS

FIG. 1 is a schematic view of an electronic device according to an embodiment.

FIG. 2 is a schematic view of an electronic device according to another embodiment.

FIG. 3 is a cross-sectional schematic view of an electronic device according to another embodiment.

FIG. 4 is a cross-sectional schematic view of an electronic device according to another embodiment.

FIG. 5 is a transmission electron microscopy (TEM) image of the quantum dots prepared in Reference Example 1.

FIG. 6 is a Fourier transform infrared (FTIR) measurement graph showing transmittance (percent, %) versus wavenumber (inverse centimeters, cm⁻¹) for the quantum dots of Reference Example 1 and Example 1.

FIG. 7 is a visible-infrared (Vis-IR) absorption spectrum graph illustrating absorption (arbitrary units) versus wavelength (nanometers, nm) of the quantum dots of Reference Example 1 and Example 1.

FIG. 8 is a graph showing the measured source-drain current (ampere, A) versus gate voltage (V) (IDS-VG) of a FET device including quantum dots in a semiconductor layer according to Example 2.

FIG. 9 is a graph illustrating current density (milliampere per square centimeter, mA/cm²) when voltage (V) is applied to a FET device including quantum dots of Reference Example 1 in a semiconductor layer without irradiating visible-IR light (Dark J-V) or while irradiating visible-IR light (Photo J-V).

FIG. 10 is a graph showing external quantum efficiency (EQE) (percent, %) versus wavelength (nm) of a photodiode device containing quantum dots of Reference Example 1.

FIG. 11 is a graph showing EQE (%) versus wavelength (nm) of a photodiode device containing quantum dots of Example 1.

FIG. 12 is a graph showing EQE (%) versus wavelength (nm) of a photodiode device containing the quantum dots of Reference Example 1, while changing voltages are applied.

FIG. 13 is a graph showing EQE (%) versus wavelength (nm) of a photodiode device containing the quantum dots of Example 1, while changing voltages are applied.

FIG. 14 is a graph showing EQE (%) versus voltages (V) of a photodiode device containing quantum dots of Reference Example 1.

FIG. 15 is a graph showing EQE (%) versus voltages (V) of a photodiode device containing the quantum dots of Example 1.

FIG. 16 is a graph showing intensities (a.u.) of photoelectrons generated from a thin film (OLAM QD) including the quantum dots of Reference Example 1 and a thin film (MPD QD) including the quantum dots of Example 1, measured with respect to the energies (electronvolt, eV) applied to each thin film.

### DETAILED DESCRIPTION

Advantages and characteristics of this disclosure, and a method for achieving the same, will become evident referring to the following embodiments together with the drawings attached hereto. However, the embodiments should not be construed as being limited to the embodiments set forth herein. If not defined otherwise, all terms (including technical and scientific terms) in the specification may be defined as commonly understood by one skilled in the art. The terms defined in a generally-used dictionary may not be interpreted ideally or exaggeratedly unless clearly defined.

In addition, unless explicitly described to the contrary, the word “comprise,” and variations such as “comprises” or “comprising,” will be understood to imply the inclusion of stated elements but not the exclusion of any other elements. Further, the singular includes the plural unless mentioned otherwise.

As used herein, the term “and/or” includes any and all combinations of one or more of the associated listed elements. An expression like “at least one,” when preceding a list of elements, modifies the entire list of elements, not individual elements of the list.

The terms “first,” “second,” “tertiary,” etc. may be used to describe various elements, components, regions, layers, etc., but these elements, components, regions, layers, etc. should not be limited by these terms. These terms are used to distinguish one element, component, domain, layer, etc. from another element, component, domain, layer, etc. Accordingly, “the first element,” “component,” “region,” “layer,” etc. described below may be referred to as a second element, component, region, layer, etc. without departing from the disclosure of the present embodiment.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

The terminology used in this specification is for the purpose of describing particular implementations and is not intended to be limiting. Unless specifically stated otherwise, “or” may also mean “and/or”.

In the drawings, the thickness of layers, films, panels, regions, etc., may be or are exaggerated for clarity. Like reference numerals designate like elements throughout the specification.

In this specification, when a first element, such as a layer, film, region, or plate, is said to be “on” a second element, this includes not only cases where it is directly on another portion, but also cases where there is another element or portion therebetween. Conversely, when a portion is “directly on” another portion, it means that there are no other elements or portions therebetween.

Hereinafter, as used herein, when a definition is not otherwise provided, “substituted” refers to replacement of hydrogen of a compound, a group, or moiety by at least one of a substituent such as a C1 to C30 alkyl group, a C2 to C30 alkenyl group, a C2 to C30 alkynyl group, a C2 to C30 epoxy group, a C2 to C30 alkylester group, a C3 to C30 alkenylester group (e.g., an acrylate group or a methacrylate group), a C6 to C30 aryl group, a C7 to C30 alkylaryl group (e.g., a 4-methylphenyl group), a C7 to C30 arylalkyl group (e.g., a benzyl group, a C1 to C30 alkoxy group, a C1 to C30 heteroalkyl group, a C3 to C30 heteroalkylaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a thiocyanate group (—SCN), a cyano group (—CN), an amino group (—NRR′ wherein R and R′ are each independently hydrogen or a C1 to C6 alkyl group), an azido group (—N₃), an amidino group (—C(═NH)NH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof. The total number of carbon atoms in a group is exclusive of any substituents, for example a —CH2CH2CN group is a substituted C2 alkyl group.

Additionally, when a definition is not otherwise provided hereinafter, “hetero” means including 1 to 3 heteroatoms that may be the same or different, such as of N, O, S, Si, or P.

As used herein, an “alkyl group” is, for example, a monovalent linear or branched or cyclic saturated aliphatic hydrocarbon group which may optionally include one or more substituents.

Additionally, “aliphatic” means a C1 to C30 linear or branched or cyclic non-aromatic saturated or unsaturated hydrocarbon group (e.g., C1 to C30 alkyl, C2 to C30 alkenyl, C2 to C30 alkynyl), and “aromatic” means a C6 to C30 aryl group or a C2 to C30 heteroaryl group.

As used herein, the phrase “external quantum efficiency” (EQE) is a ratio of the number of photons emitted from a device to the number of electrons passing through the device and can be a measurement as to how efficiently a given device converts electrons to photons and allows the photons to escape. The EQE can be determined by the following equation:

EQE=an efficiency of injection x a (solid-state) quantum yield x an efficiency of extraction
wherein the efficiency of injection is a proportion of electrons passing through the device that are injected into the active region, the quantum yield is a proportion of all electron-hole recombination in the active region that are radiative and produce photons, and the efficiency of extraction is a proportion of photons generated in the active region that escape from the given device. As used herein, a maximum EQE is a greatest value of the EQE.

IR absorbing materials that absorb light in a near infrared (IR) region have recently been applied in the field of IR imaging, such as night vision, tracking, remote temperature sensing, short-ranged wireless communications, spectroscopy, solar cells, bio-imaging, augmented/virtual reality (AR/VR), Lidar (light detection and ranging), and ToF (time of flight) sensors. In particular, with the recent advancement of technologies such as autonomous driving, drones, and robots, sensors that recognize light beyond the visible region, i.e., light that humans cannot perceive are emerging as important components in various devices such as machines, automobiles, and robots.

However, existing silicon has weak absorption in the IR region and a quantum efficiency (QE) of less than 20%, limiting its use in the IR region. In particular, in the short wavelength IR (SWIR) region, that is, the wavelength range of approximately 1 μm or more, which is less affected by external light, less scattering by water or small particles, and has excellent eye safety, the QE of silicon is close to 0%, requiring replacement with other materials.

A sensor using InGaAs (indium-gallium-arsenide) is known as a material that can replace silicon as a sensor material in the SWIR region, but it is currently very expensive, which limits its commercialization in various fields. To avoid the high price and preparation process issues of InGaAs, products using PbS (lead-sulfur) quantum dots (QDs) have recently been released. However, due to environmental issues related to lead (Pb), there is a need to develop IR absorbing materials that can replace lead.

Except for indium phosphide (InP), there are many challenges in the synthesis of quantum dots based on (i.e., containing) indium and Group V elements that can absorb long-wavelength light, such as infrared or near-infrared. For example, there have been attempts to prepare indium antimonide (InSb) based (i.e., InSb-containing quantum dots using indium amide and antimony amide precursors dissolved in trioctylphosphine or oleylamine. However, this preparing method has problems with reproducibility due to the volatility of the antimony precursor, and in particular, the size distribution of the prepared quantum dots is poor, requiring an extensive size selection process. The reaction and preparation yields are also poor. In addition, a method (hereinafter, a co-reduction method) has been proposed in which indium chloride dissolved in trioctylphosphine and antimony silylamide dissolved in toluene are used as precursors to carry out the reaction in the presence of a superhydride. However, this method also has problems with reproducibility, poor size distribution of the prepared quantum dots, low preparation yield, and generation of a large amount of insoluble byproducts. In addition, when indium chloride and a silylamide of a Group V element, such as antimony (Sb), are reacted as a precursor in an organic medium in the presence of a superhydride, but in the absence of trioctylphosphine, the produced indium-containing quantum dots are more likely to agglomerate and may exhibit higher electrical resistance.

That is, in the case of InSb quantum dots or InAs quantum dots prepared by the above methods, their desirable characteristics are significantly lower than those of existing PbS quantum dots, and much improvement is needed for application in various fields as SWIR materials.

The inventors of the present invention have developed a quantum dot including a Group IIIA element and a Group VA element of the periodic table of elements, having a ligand derived from an aliphatic hydrocarbon compound substituted with a hydroxyl group (—OH) and a thiol group (—SH) on the surface thereof, and having an absorption peak wavelength of greater than or equal to about 1,000 nm in a visible-infrared (Vis-IR) absorption spectrum.

The quantum dot is capable of absorbing wavelengths in the SWIR region of greater than or equal to about 1,000 nm without including hazardous heavy metals such as mercury, cadmium, and lead, and when a device including the quantum dot in a semiconductor layer is manufactured and external quantum efficiency (EQE) is measured, the EQE in the absorption wavelength region is as high as 10% or more, and further exhibits excellent charge mobility, so that they can be used as an environmentally friendly SWIR absorbing material applicable to various fields.

The quantum dot may have an average particle size of greater than or equal to about 2.5 nm.

As described above, since quantum dots can control the energy bandgap by controlling their particle size and composition, the quantum dots according to an embodiment can have a particle size within a certain range in order to have an absorption peak wavelength in the region of greater than or equal to about 1,000 nm region. For example, the average particle size of the quantum dot may be greater or equal to about 2.5 nm, greater or equal to about 2.7 nm, greater or equal to about 3.0 nm, greater or equal to about 3.2 nm, greater or equal to about 3.5 nm, greater or equal to about 3.7 nm, greater or equal to about 4.0 nm, greater or equal to about 4.2 nm, greater or equal to about 4.5 nm, greater or equal to about 4.7 nm, greater or equal to about 5.0 nm, greater or equal to about 5.2 nm, greater or equal to about 5.5 nm, greater or equal to about 5.7 nm, greater or equal to about 6.0 nm, greater or equal to about 6.5 nm, greater or equal to about 7.0 nm, greater or equal to about 7.5 nm, greater or equal to about 8.0 nm, greater or equal to about 8.5 nm, greater or equal to about 9.0 nm, greater or equal to about 9.5 nm, greater or equal to about 10.0 nm, greater or equal to about 10.5 nm, greater or equal to about 11.0 nm, greater or equal to about 11.5 nm, greater or equal to about 12 nm, greater or equal to about 13 nm, greater or equal to about 15 nm, greater or equal to about 17 nm, greater or equal to about 18 nm, or greater or equal to about 19 nm. In addition, for example, the average particle size of the quantum dot may be less than or equal to about 30 nm, less than or equal to about 28 nm, less than or equal to about 25 nm, less than or equal to about 23 nm, less than or equal to about 20 nm, less than or equal to about 18 nm, less than or equal to about 17 nm, less than or equal to about 15 nm, less than or equal to about 13 nm, less than or equal to about 12 nm, less than or equal to about 11 nm, less than or equal to about 10 nm, less than or equal to about 9.5 nm, less than or equal to about 9 nm, less than or equal to about 8.5 nm, less than or equal to about 8 nm, less than or equal to about 7.5 nm, less than or equal to about 7 nm, less than or equal to about 6.5 nm, less than or equal to about 6 nm, less than or equal to about 5.5 nm, less than or equal to about 5.0 nm, less than or equal to about 4.5 nm, less than or equal to about 4.0 nm, less than or equal to about 3.5 nm, less than or equal to about 3.0 nm, or less than or equal to about 2.7 nm.

As used herein, the particles size of the quantum dot may be a particle diameter. The size or the diameter of the quantum dot may be an equivalent diameter thereof that is obtained by a calculation involving a conversion of a two-dimensional area of a transmission electron microscopy image of a given quantum dot into a circle.

A particle size distribution of a plurality of the quantum dots (e.g., a standard deviation thereof) may be less than or equal to about 12%, less than or equal to about 10%, or less than or equal to about 9% of the average size of the plurality of quantum dots. Average particle size and particle size distribution can be determined, for example, by analysis of a two-dimensional image obtained via transmission electron microscopy.

The quantum dot can exhibit the formation of a superlattice structure in transmission electron microscopy analysis. The quantum dots according to an embodiment prepared in the examples described below may be prepared as particles having a very uniform size and shape, as may be confirmed through the transmission electron microscope (TEM) images attached to the specification of the present application. Accordingly, it is thought that excellent characteristics of an electronic device including the quantum dot according to an embodiment may be secured.

In an embodiment, the quantum dot may have an absorption peak wavelength in the visible-infrared absorption spectrum of greater than or equal to 1,000 nm, for example, greater than or equal to 1,100 nm, greater than or equal to 1,200 nm, greater than or equal to 1,300 nm, greater than or equal to 1,400 nm, greater than or equal to 1,500 nm, greater than or equal to 1,600 nm, or greater than or equal to 1,700 nm, and can have an absorption peak wavelength in the visible-infrared absorption spectrum of less than or equal to 1,800 nm, less than or equal to 1,700 nm, less than or equal to 1,600 nm, less than or equal to 1,500 nm, less than or equal to 1,400 nm, or less than or equal to 1,300 nm.

The Group IIIA element of the quantum dot may include indium (In), aluminum (Al), gallium (Ga), or a combination thereof. For example, the Group IIIA element of the quantum dot may include indium (In), gallium (Ga), or a combination thereof. For example, the Group IIIA element of the quantum dot may include indium (In).

The Group VA element of the quantum dot may include arsenic (As), antimony (Sb), bismuth (Bi), or a combination thereof. For example, the Group VA element of the quantum dot may include arsenic (As), antimony (Sb), or a combination thereof. For example, the Group VA element of the quantum dot may include arsenic (As).

For example, the quantum dot according to an embodiment may include indium (In) and arsenic (As), and optionally may further include gallium (Ga) and/or antimony (Sb). For example, the quantum dot may include indium (In) and arsenic (As), and optionally may further includes antimony (Sb). For example, the quantum dot may be composed of indium (In) and arsenic (As).

In an embodiment, the quantum dot may have a molar ratio of the Group VA element (e.g., arsenic) to the Group IIIA element (e.g., indium) of greater or equal to about 0.5:1, for example, greater or equal to about 0.55:1, greater or equal to about 0.6:1, greater or equal to about 0.65:1, greater or equal to about 0.7:1, greater or equal to about 0.75:1, greater or equal to about 0.8:1, greater or equal to about 0.85:1, greater or equal to about 0.9:1, or greater or equal to about 0.95:1, and also a molar ratio of the Group VA element (e.g., arsenic) to the Group IIIA element (e.g., indium) of less than or equal to about 1.0:1, for example, less than or equal to about 0.95:1,less than or equal to about 0.9:1, less than or equal to about 0.85, less than or equal to about 0.8:1, less than or equal to about 0.75:1, less than or equal to about 0.7:1, less than or equal to about 0.65:1, less than or equal to about 0.6:1, or less than or equal to about 0.55:1. For example, stated another way, the molar ratio of the Group

IIIA element to the Group VA element in the quantum dot may be about 1:1 to about 2:1, for example, about 1:1 to about 1.8:1, about 1:1 to about 1.7:1, about 1:1 to about 1.6:1, about 1:1 to about 1.5:1, about 1:1 to about 1.4:1, about 1:1 to about 1.3:1, about 1:1 to about 1.2:1, about 1:1 to about 1.1:1, for example, may be about 1:1, but is not limited thereto.

The molar ratio of elements in quantum dots may be confirmed by inductively coupled plasma atomic emission spectrometry (ICP-AES, etc.), energy dispersive spectrometry (EDS), etc., but is not limited to these methods.

The ligand present on the surface of the quantum dot may be derived from a linear or branched aliphatic hydrocarbon compound having 2 to 30 carbon atoms substituted with one or more hydroxyl groups and one or more thiol groups. For example, the ligand may be derived from a linear or branched aliphatic hydrocarbon compound having 2 to 20 carbon atoms substituted with one or more hydroxyl groups and one or more thiol groups, or may be derived from a linear or branched aliphatic hydrocarbon compound having 2 to 10 carbon atoms substituted with one or more hydroxyl groups and one or more thiol groups. In an embodiment, the compound may be 1-hydroxy-2-mercaptoethane (ME), 1,2-dihydroxy-3-mercapto propane (MPD), or a combination thereof, but is not limited these compounds.

Without intending to be bound by a particular theory, the smaller the carbon number of the aliphatic hydrocarbon compound from which the ligand is derived, i.e., when the quantum dot surface is modified with a ligand having a shorter carbon chain length, the charge mobility of the electronic device including the quantum dot may further increase. On the other hand, when the carbon number of the ligand is reduced to include a shorter ligand, dispersion of the quantum dot in the solvent may be difficult. In this case, there is also a possibility that the external quantum efficiency (EQE) may decrease due to aggregation of quantum dots. Therefore, by controlling the carbon number of the ligand present on the surface of a quantum dot according to an embodiment, the electrical characteristics and/or external quantum efficiency of a device including the quantum dot can be controlled.

The quantum dot according to the embodiment may be prepared by a preparation method as described below. That is, another embodiment relates to a method for preparing a quantum dot according to the above-described embodiment.

A method of preparing a quantum dot according to an embodiment may include,
preparing a precursor solution of a Group IIIA element including a precursor of a Group IIIA element, a first amine compound, and optionally a phosphine compound;
preparing a precursor solution of a Group VA element including a precursor of a Group VA element and a second amine compound;
while heating the precursor solution of the Group IIIA element, mixing the precursor solution of the Group VA element with the precursor solution of the Group IIIA element and reacting the precursor of the Group IIIA element and the precursor of the Group VA element;
after the reaction, obtaining a quantum dot including a Group IIIA element and a Group VA element, and including the first amine compound, the second amine compound, the optional phosphine compound on a surface of the quantum dot; and
replacing the first amine compound, the second amine compound, the phosphine compound, or the combination thereof on the surface of the obtained quantum dot with an aliphatic hydrocarbon compound substituted with a hydroxy group (—OH) and a thiol group (—SH).

As described above, the Group IIIA element may include indium (In), aluminum (Al), gallium (Ga), or a combination thereof, and the Group VA element may include arsenic (As), antimony (Sb), bismuth. (Bi), or a combination thereof.

The precursor of the Group IIIA element and the precursor of the Group VA element may include a halide, a sulfide, an amine-containing compound of the Group IIIA element and the Group VA element, or a combination thereof.

For example, the precursor of the Group IIIA element may include a halide of the Group IIIA element, for example, a fluoride of the Group IIIA element, a chloride of the Group IIIA element, a bromide of the Group IIIA element, or an iodide of the Group IIIA element. For example, the precursor of the Group IIIA element may include indium fluoride, indium chloride, indium bromide, indium iodide, aluminum fluoride, aluminum chloride, aluminum bromide, aluminum iodide, gallium fluoride, gallium chloride, gallium bromide, or gallium iodide, and may include, for example, indium fluoride, indium chloride, indium bromide, or indium iodide, and in an embodiment, the precursor of the Group IIIA element may include indium chloride, but is not limited thereto.

For example, the precursor of the Group VA element may include a halide or an amine-containing compound including the Group VA element, for example, the precursor of the Group VA element may include a halide of arsenic (As), antimony (Sb), bismuth (Bi), or a combination thereof, or an amine-containing compound of arsenic (As), antimony (Sb), bismuth (Bi), or a combination thereof. For example, the precursor of the Group VA element may include a halide of arsenic (As) or antimony (Sb), or an amine-containing compound of arsenic (As) or antimony (Sb). In an embodiment, the precursor of the Group VA element may include dimethylaminoarsine, tris(dimethylamino) arsine, arsine chloride (AsCl₃), arsine bromide (AsBr₃), arsine iodide (Asl₃), or a combination thereof, but is not limited thereto.

The first amine compound and the second amine compound may be the same or different, and may each independently have at least one C1 to C40 aliphatic hydrocarbon group, at least one C6 to C40 aromatic hydrocarbon group, or a combination thereof. For example, the first amine compound and the second amine compound may each independently include RNH₂, R₂NH, or a combination thereof (wherein R each independently represents a C5 to C40 substituted or unsubstituted aliphatic hydrocarbon group, a C6 to C40 substituted or unsubstituted aromatic hydrocarbon group, or a combination thereof). For example, the first amine compound and the second amine compound may each independently include an amine having a C6 to C40 alkenyl group, an amine having a C6 to C40 alkyl group, or a combination thereof. In an embodiment the first amine compound and the second amine compound may not include a tertiary amine. For example, the first amine compound and the second amine compound may each independently include, but are not limited to, oleylamine, butylamine, octylamine, dioctylamine, dodecylamine, hexadecylamine, hexylamine, propylamine, aniline, benzylamine, octadecylamine, or a combination thereof.

The phosphine compound may include a compound having at least one (two e.g., two or three) C1 to C40 aliphatic hydrocarbon group, at least one (e.g., two or three) C6 to C40 aromatic hydrocarbon group, or a combination thereof, linked to a phosphorus atom. For example, the phosphine compound may include R₃PO, R₂HPO, RH₂PO, R₃P, R₂PH, RPH₂, RPO(OH)₂, RHPOOH, R₂POOH, or a combination thereof (wherein R each independently represents a C5 to C40 substituted or unsubstituted aliphatic hydrocarbon group, a C6 to C40 substituted or unsubstituted aromatic hydrocarbon group, or a combination thereof). For example, the phosphine compound may include an alkyl or aryl phosphine of the formulas R₃P, R₂PH, or a combination thereof, and may include, but is not limited to, trioctylphosphine (TOP), diphenylphosphine, or a combination thereof.

In an embodiment, the reaction may be performed in the absence of a phosphine compound (e.g., in the absence of trioctylphosphine). Without wishing to be bound by any particular theory, the use of TOP may result in the production of elongated particles, and thus, a more uniform population of particles may be prepared by not using a phosphine compound, such as trioctylphosphine, for example, during the reaction or prior to the particle formation. In an embodiment, a phosphine compound may be present, but is not trioctylphosphine.

The precursor solution of the Group IIIA element may be prepared by further including first mixing the precursor of the Group IIIA element and the first amine compound, and then degassing with nitrogen gas before mixing the optional phosphine compound. By removing oxygen in the solution through the degassing process, oxidation of the precursor material and the quantum dots prepared therefrom may be suppressed, and the reactants and products may be maintained more stably.

The mixing and reacting of the precursor solution of the Group IIIA element and the precursor solution of the Group VA element may include heating the precursor solution of the Group IIIA element to greater than or equal to about 200° C., for example, greater than or equal to about 220° C., greater than or equal to about 230° C., greater than or equal to about 250° C., greater than or equal to about 270° C., greater than or equal to about 280° C., greater than or equal to about 300° C., greater than or equal to about 310° C., or greater than or equal to about 320° C., and then injecting the precursor solution of the Group VA element into the precursor solution of the Group IIIA element to cause a reaction. The reaction temperature may be, for example, less than or equal to about 380° C., less than or equal to about 360° C., less than or equal to about 350° C., less than or equal to about 345° C., less than or equal to about 340° C., less than or equal to about 330° C., less than or equal to about 320° C., less than or equal to about 310° C., less than or equal to about 300° C., or less than or equal to about 290° C.

In an embodiment, the precursor solution of the Group VA element may be preheated to a certain temperature, for example, about 50° C., before being injected into the precursor solution of the Group IIIA element.

The amount of the precursor of the Group IIIA element and the precursor of the Group VA element in each solution and thus in the reaction may be adjusted to an appropriate range in consideration of the energy bandgap and the range of the maximum absorption peak wavelength of the quantum dot prepared therefrom. For example, the amounts of the precursor solutions of the elements may be selected such that the molar ratio of the Group VA element to the Group IIIA element in the quantum dot is in a range as described above, for example of greater than or equal to about 0.5:1 and less than or equal to about 1.0:1, for example, a molar ratio of about 1:1.

When the quantum dots including the Group IIIA element and the Group VA element are prepared by the reaction of the precursor solution of the Group IIIA element and the precursor solution of the Group VA element, the temperature of the solution including the quantum dots may be cooled to room temperature, for example, a temperature of about 25° C., and then, by adding a nonsolvent that is not miscible with a solvent included in the reactants, for example the first amine compound and/or the second amine compound, the formed quantum dots may be separated as a precipitate from the solution including the quantum dots. The precipitated quantum dots may be separated from the solution, for example by using a method such as centrifugation after addition of the nonsolvent.

The nonsolvent may include, for example, a C5 to C10 linear hydrocarbon, a C4 to C10 cyclic hydrocarbon, a C1 to C10 alcohol, a ketone, a nitrile, or a combination thereof. For example, the nonsolvent may include, but is not limited to, hexane, n-butanol, and the like.

The separated quantum dots may be washed by resuspending them in hexane, n-butanol, or the like, and separated, for example by additional centrifugation.

The quantum dots separated as described above may be subjected to a ligand substitution reaction in which the first amine compound, the second amine compound, and/or the optional phosphine compound present on the surface of the quantum dot are replaced with an aliphatic hydrocarbon compound substituted with a hydroxyl group and a thiol group present on the surface of the quantum dot according to an embodiment, after being dispersed in an appropriate solvent, if necessary.

The ligand substitution reaction may include contacting the separated quantum dot, optionally in a solution of a nonpolar organic solvent with a solution including a compound to be substituted, for example, an aliphatic hydrocarbon compound substituted with a hydroxyl group and a thiol group capable of providing a ligand present on the surface of the quantum dot according to an embodiment, in, for example, a solution including a polar organic solvent. For example, when the separated quantum dots are dispersed in a suitable organic solvent, for example, a non-polar organic solvent, and the dispersion is added to a solution including the compound to be substituted and a polar organic solvent, phase separation of the polar organic solvent and the non-polar organic solvent occurs. In this process, the quantum dot moves to the polar organic solvent in which the compound to be substituted is dissolved by phase transfer, and the first amine compound, the second amine compound, and/or the optional phosphine compound present on the surface of the quantum dot are separated from the quantum dot. Accordingly, the surface of the quantum dot moved into the polar organic solvent may be modified by a hydrocarbon compound substituted with a hydroxyl group and a thiol group dissolved in the polar organic solvent, so that the ligand substitution reaction can be completed. The ligand-substituted quantum dots can be separated by separating the polar organic solvent layer through phase separation of the polar organic solvent and the non-polar organic solvent, or by centrifugation. The separated quantum dots can be obtained as final products through washing and resuspension processes using additional solvents.

The polar organic solvent and non-polar organic solvent that can be used in the ligand substitution reaction can be any of the polar organic solvents and non-polar organic solvents commonly used for phase separation reactions in the relevant technical field, and are not limited to a specific type. For example, the nonpolar organic solvent may be an aliphatic hydrocarbon compound having 4 to 30 carbon atoms, such as hexane, octane, cyclohexane, etc., and the polar organic solvent may be DMF (N,N-dimethylformamide), DMSO (dimethyl sulfoxide), etc., but are not limited thereto.

The amount of the ligand present on the surface of the quantum dot according to an embodiment is not particularly limited, but for example, the ligand substitution reaction may be performed by dissolving the aliphatic hydrocarbon compound substituted with the hydroxyl group and the thiol group in a polar organic solvent in which the ligand substitution reaction is performed in an amount sufficient to uniformly coat the entire surface of the quantum dot. For example, the amount of the ligand compound present on the surface of the quantum dot according to an embodiment may be in a range of about 10 wt % to about 80 wt % based on the ligand density of the quantum dot. For example, the amount of the ligand may be about 10 wt % to about 75 wt %, for example, about 15 wt % to about 75 wt %, about 15 wt % to about 70 wt %, about 20 wt % to about 75 wt %, about 20 wt % to about 70 wt %, about 20 wt % to about 65 wt %, about 20 wt % to about 60 wt %, about 25 wt % to about 75 wt %, about 25 wt % to about 70 wt %, about 25 wt % to about 65 wt %, about 30 wt % to about 75 wt %, about 30 wt % to about 70 wt %, about 30 wt % to about 65 wt %, about 30 wt % to about 60wt %, about 35 wt % to about 75 wt %, about 35 wt % to about 70 wt %, about 35 wt % to about 65 wt %, about 40 wt % to about 75 wt %, about 40 wt % to about 70 wt %, about 40 wt % to about 65 wt %, or about 40 wt % to about 60 wt %, based on the ligand density, but is not limited to these ranges.

In order to compare the absorption characteristics of the quantum dots including the first amine compound, the second amine compound, and/or the phosphine compound on the surface thereof, and the quantum dots having the aliphatic ligands on the surface thereof according to an embodiment, and/or the characteristics of the devices including the quantum dots, the absorption spectrum and charge mobility, etc. of the formed quantum dots may be measured before substituting the ligand of the quantum dots. This will be explained in detail through the examples described below.

According to an embodiment, a quantum dot prepared by the above method may exhibit significantly increased charge mobility and external quantum efficiency, etc., compared to the quantum dots having amine-containing compounds and/or phosphine-containing compounds on their surfaces, as the ligand of the quantum dot according to an embodiment is derived from an aliphatic hydrocarbon compound having a, i.e., at least one hydroxyl group and a, i.e., at least one thiol group. Therefore, the quantum dot according to an embodiment can exhibit excellent charge mobility and external quantum efficiency while absorbing light in the infrared range of greater than or equal to about 1,000 nm, and a semiconductor layer including the quantum dot has potential applications in solar cells, image sensors, and light absorbing layers of infrared sensors (IR sensors), channel materials of field effect transistors (FETs), light emitting materials of near-infrared quantum dot light emitting diodes (NIR QD LEDs), and thermoelectric materials.

Accordingly, another embodiment provides an electronic device including the quantum dots described above.

The electronic device may include a solar cell, a photodetector, a field effect transistor, a flash memory, a photoelectrochemical device, or a combination thereof. The quantum dot according to an embodiment may be applied to a light absorbing layer or a semiconductor layer of a solar cell and a photodetector, and absorb light in the visible light range and near-infrared region to generate electrical energy and signals. Additionally, the quantum dot may be used as n-type or p-type channel layers of transistors and can also be applied to floating gates of flash memory. The quantum dot can also be applied to the photoelectric conversion layer of a photoelectrochemical cell that receives light, decomposes water to produce hydrogen and oxygen, or reduces CO₂ to produce organic compounds.

An electronic device according to an embodiment may include a first electrode and a second electrode spaced apart from each other; and a semiconductor layer including the aforementioned quantum dot between the first electrode and the second electrode.

The first electrode and the second electrode may have main surfaces facing each other, and the semiconductor layer may be interposed between the first electrode and the second electrode. The semiconductor layer may be electrically connected to the first electrode, the second electrode, or a combination thereof.

A thickness of the semiconductor layer may be greater than or equal to about 10 nm, for example, greater than or equal to about 20 nm, greater than or equal to about 30 nm, greater than or equal to about 40 nm, greater than or equal to about 50 nm, or greater than or equal to about 100 nm. The thickness of the semiconductor layer may be less than or equal to about 1 μm, for example, less than or equal to about 900 nm, less than or equal to about 800 nm, less than or equal to about 700 nm, less than or equal to about 600 nm, less than or equal to about or 500 nm, less than or equal to about 400 nm, less than or equal to about 300 nm, less than or equal to about 200 nm, less than or equal to about 100 nm, or less than or equal to about or 60 nm.

In an electronic device of an embodiment, the semiconductor layer can absorb near-infrared light of greater than or equal to about 1,000 nm, for example, greater than or equal to about 1,100 nm, greater than or equal to about 1,200 nm, greater than or equal to about 1,300 nm, greater than or equal to about 1,400 nm, or greater than or equal to about 1,500 nm, to generate a photocurrent.

The semiconductor layer of the electronic device may have a charge mobility of greater than or equal to about 10⁻⁵ cm²/ Vs, for example, greater than or equal to about 10⁻⁴ cm²/ Vs, for example, greater than or equal to about 1×10⁻³ cm²/ Vs.

In an electronic device of an embodiment, the semiconductor layer may be configured to have a responsivity of greater than or equal to about 2×10⁻¹ amperes per watt (A/W), or greater than or equal to about 3×10⁻¹ A/W when irradiated with light having a wavelength of about 1.55 μm.

In an electronic device of an embodiment, the semiconductor layer may be configured to have an external quantum efficiency (EQE) of greater than or equal to about 10% when irradiated with light having a wavelength of 1.55 μm.

The electronic device may include a carrier auxiliary layer between the semiconductor layer and the first electrode, between the semiconductor layer and the second electrode, or both. The carrier auxiliary layer may include a metal oxide. The metal oxide may include molybdenum metal oxide, zinc metal oxide, or a combination thereof.

In an embodiment, the electronic device may be a field effect transistor (FET). The electronic device may further include a third electrode facing the semiconductor layer; and an insulating layer between the semiconductor layer and the third electrode.

The electronic device may be configured to have a field effect mobility of greater than or equal to about 10⁻⁵ cm²/ Vs. The above electronic device can be configured to have a field effect mobility of greater than or equal to about 10⁻⁴ cm²/ Vs, for example, greater than or equal to about 1×10⁻³ cm²/ Vs, or greater than or equal to about 2.5×10⁻³ cm²/ Vs.

In another embodiment, the semiconductor layer may be in contact, e.g., in direct contact with the first electrode and the second electrode. The first electrode and the second electrode may be arranged to form an interdigitated form. The spacing between the first electrode and the second electrode may be greater than or equal to about 1 μm, for example, greater than or equal to about 2 μm, greater than or equal to about 3 μm, greater than or equal to about 4 μm, or greater than or equal to about 5 μm.

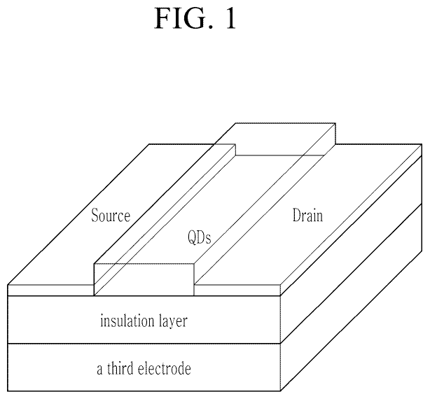

FIG. 1 is a schematic perspective view of an electronic device according to an embodiment. Referring to FIG. 1, a semiconductor layer including a quantum dot including a Group IIIA element and a Group VA element according to an embodiment may be disposed between a first electrode (e.g., a source electrode) and a second electrode (e.g., a drain electrode). The electronic device further may include a third electrode (e.g., a gate electrode) facing the semiconductor layer, and an insulating layer may be disposed between the semiconductor layer and the third electrode.

Materials for the first electrode and the second electrode are not particularly limited and may be appropriately selected by one of ordinary skill in the art. Examples of materials for the first electrode and the second electrode may include a metal such as gold, nickel, aluminum, and platinum, a conductive polymer, and a conductive ink, but is not limited thereto. Each thickness of the first electrode and the second electrode maybe appropriately selected. For example, the thickness of the first electrode (or the second electrode) may be greater than or equal to about 40 nm, for example, greater than or equal to about 100 nm, and less than or equal to about 400 μm, but is not limited thereto.

The material of the third electrode (e.g., gate electrode) is not particularly limited and may be appropriately selected. For example, the third electrode may include a metal film, a conductive polymer film, a conductive film made of conductive ink or paste, doped silicon, etc., but is not limited thereto. Examples of the material of the third electrode may include a conductive polymer such as aluminum, gold, silver, chromium, indium tin oxide, poly(3,4-ethylene dioxythiophene) doped with polystyrene sulfonate (PSS-PEDOT), a conductive ink/paste such as a carbon black/graphite or colloidal silver dispersion or a silver ink (Ag ink) in polymer binders, but are not limited thereto. The third electrode layer may be manufactured by vacuum deposition or sputtering of a metal or a conductive metal oxide, spin coating of a conductive polymer solution or conductive ink, coating by casting or printing, or doping of a substrate. A thickness of the third electrode layer is not particularly limited and may be appropriately selected. For example, the thickness of the third electrode including a metal thin film may be greater than or equal to about 10 nm and less than or equal to 200 nm, the third electrode including a polymer conductor may be about 1 μm to about 10 μm, and the thickness of the gate electrode including a carbon composite such as a carbon nanotube (CNT) may be greater than or equal to about 100 nm, for example, about 1 μm to about 10 μm, but are not limited thereto.

The insulating layer may separate the third electrode from the first electrode, the second electrode, and the semiconductor layer 30. The insulating layer may include a thin film of an inorganic material or a film of an organic polymer. Examples of inorganic materials may include silicon oxide, silicon nitride, aluminum oxide, barium titanate, and zirconium titanate, but are not limited thereto. Examples of organic polymers may include polyester, polycarbonate, poly(vinyl phenol), polyimide, polystyrene, poly(methacrylate), poly(acrylate), an epoxy resin, and the like, but are not limited thereto. A thickness of the insulating layer may vary depending on the permittivity of the insulating material and is not particularly limited. For example, the insulating layer may have a thickness of greater than or equal to about 10 nm, for example, greater than or equal to about 50 nm, or greater than or equal to about 100 nm, but is not limited thereto. The insulating layer may have a thickness of less than or equal to about 2,000 nm, for example, less than or equal to about 500 nm, but is not limited thereto. The conductivity of the insulating layer may be less than or equal to about 10-12 siemens per centimeter (S/cm), but is not limited thereto.

The first electrode, the semiconductor layer, the insulating layer, the third electrode, and the second electrode may be formed in any order and are not particularly limited.

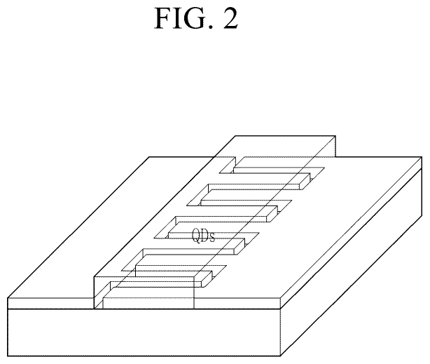

FIG. 2 is a schematic perspective view of an electronic device according to another embodiment. Referring to FIG. 2, the electronic device may include a first electrode and a second electrode spaced apart from each other, and a semiconductor layer including a quantum dot according to an embodiment between the first and second electrodes. The semiconductor layer may be in contact with the first and second electrodes. The electrodes and semiconductor layers are described in FIG. 1.

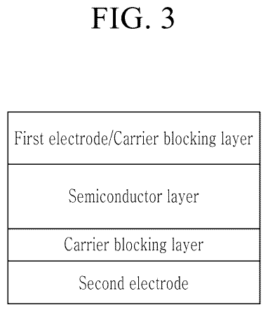

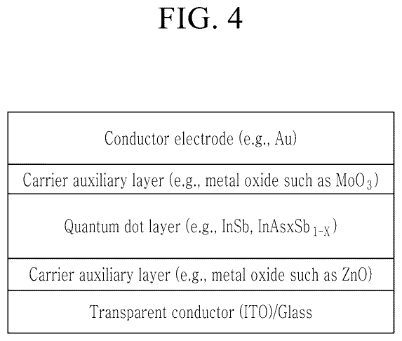

FIGS. 3 and 4 illustrate cross-sectional views of electronic devices according to another embodiment, respectively. Referring to FIGS. 3 and 4, the device may include a semiconductor layer disposed between a first electrode (e.g., indium tin oxide) and a second electrode (e.g., aluminum). The semiconductor layer may include the quantum dot according to an embodiment. The device can form a metal-semiconductor Schottky junction or heterojunction photodiode. The semiconductor layer may include a layer exhibiting p-type characteristics. The semiconductor layer may include a layer exhibiting n-type characteristics. The semiconductor layer may include a layer exhibiting i-type characteristics. The semiconductor layer may be a multilayer structure, and each layer may be configured to represent n type, i type, p type, or a combination thereof. A carrier auxiliary layer (a carrier transport layer, a carrier injection layer, or a carrier blocking layer, such as PEDOT: PSS, a metal oxide, LiF, etc.) may be disposed between the semiconductor layer and the first electrode, between the semiconductor layer and the second electrode, or both. The metal oxide may include zinc oxide, molybdenum oxide, or combinations thereof, but is not limited thereto. The device may include a Schottky diode.

In FIGS. 3 and 4, the first electrode and the second electrode are shown as being positioned at the upper and lower portions of each drawing, respectively, but the positions of each electrode in these drawings do not have fixed positions such as the actual upper or lower portions. That is, the first electrode shown in FIG. 3 may actually be positioned at the bottom, and the second electrode may be positioned at the top, or the transparent conductor of FIG. 4 may be positioned at the top of the device, a carrier auxiliary layer including ZnO may be positioned therebelow. A conductor electrode may be positioned at the bottom, and a second carrier auxiliary layer (e.g., a layer including MoO₃) may be positioned thereon.

Specific examples are presented below. However, the examples described below are only intended to specifically illustrate or explain the above embodiments, and the scope of the present specification should not be limited thereby.

### EXAMPLES

### Measurement Methods

### [1] Quantum Dot Photoluminescence Analysis

A photoluminescence (PL) spectrum of the manufactured quantum dots is obtained by using a photoluminescence analyzer (Model name: FLS1000, Manufacturer: Edinburgh Instruments Ltd.).

### [2] Ultraviolet (UV) Spectral Analysis

A UV spectrophotometer (Model name: Cary 5000, Manufacturer: Agilent Technologies) is used to perform UV spectral analysis to obtain a ultraviolet-visible-near infrared (UV-Visible-NIR) absorption spectrum.

### [3] TEM Analysis and EDS Analysis

A transmission electron microscope (Model name: JEM1400, Manufacturer: JEOL Inc.) is used to perform a transmission electron microscope analysis and an EDS analysis.

[4] Nuclear magnetic resonance (NMR) Analysis:

An NMR analyzer (Model name: DRX 500, Manufacturer: Bruker) is used to perform an NMR analysis.

### [5] Measurement of Electrical and Photoelectric Properties

A semiconductor parameter analyzer (Model name: 4156C manufactured by Agilent Technologies) is used to measure electrical and photoelectric properties.

### [6] Inductively Coupled Plasma Analysis

A spectro genesis spectrometer is used to perform inductively coupled plasma optical emission spectroscopy (ICP_OES).

### Reference Example 1: Preparation of InAs Quantum Dots Passivated With Oleylamine

7.2 Milliliters (ml) of oleylamine and 0.225 grams (g) of In (I) CI as an indium precursor are added to a 50 ml 3-neck flask, and degassing is performed at 60° C. for 30 minutes. When the degassing is completed, after purging with nitrogen inside the flask, 0.3 ml of TOP (trioctyl phosphine) is injected thereinto. After the TOP injection, the reactant in the flask is rapidly heated up to 280° C. within 10 minutes.

Meanwhile, in a glove box, 2 ml of oleylamine and 0.15 ml of tris (dimethylamino) arsine as a precursor compound of arsenic (As) are added to a 10 ml vial, and then heated at 50° C. for 5 minutes.

When the temperature of the flask containing the indium precursor reaches 280° C., 1.3 ml of the solution containing the arsenic precursor in the vial is extracted, and then injected into the flask containing the indium precursor to react with each other. After performing the reaction for 1 hour, the temperature of the flask is reduced to room temperature.

When the temperature of the flask decreases to room temperature, hexane and n-butanol are added in an amount of 2 ml and 30 ml, respectively, to the crude solution extracted from the flask, and then centrifuged at 6,000 revolutions per minute (rpm) for 5 minutes to obtain quantum dots. The obtained quantum dots are added to a mixture of 10 mL of hexane and 30 ml of n-butanol, and then centrifuged at 6,000 rpm for 5 minutes.

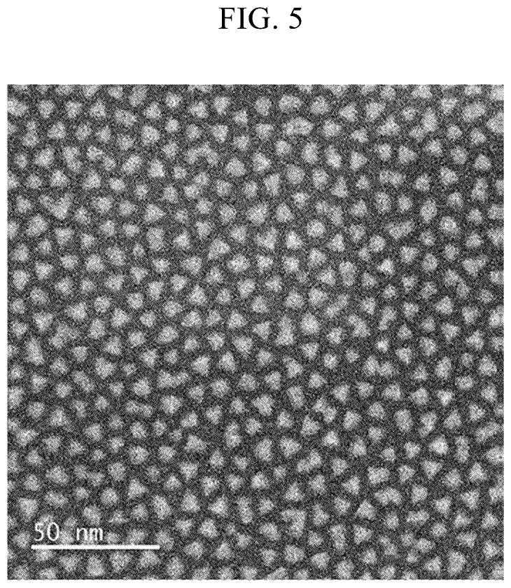

The obtained quantum dots are measured with TEM, and the quantum dots are confirmed to have an average particle diameter of about 3 nm (FIG. 5). In addition, when each amount of indium (In) and arsenic (As) in the quantum dots is measured with ICP, EDS, or the like, In and As have a molar ratio of about 1:1.

### Example 1: Preparation of InAs Quantum Dots Surface-Modified With 3-Mercapto-1,2-Propanediol (MPD)

The quantum dots (InAs-Olam) passivated with oleylamine according to Reference Example 1 are subjected to a ligand substitution reaction on their surfaces.

Specifically, 50 milligrams (mg) of the quantum dots (InAs-Olam) surface-passivated with oleylamine according to Reference Example 1 are dispersed in 2 mL of octane to prepare a suspension.

In addition, 75 microliters (μl) of butylamine and 150 μl of 1-thioglycerol (3-mercapto-1,2-propanediol) (MDP) are dissolved in 2 mL of DMF (N,N-dimethylformamide).

The suspension of the quantum dots is mixed with the prepared DMF solution, and then, vortexed for 30 seconds to induce a phase separation. Herein, if the phase separation is not clean, centrifugation is performed at 6,000 rpm for about 5 minutes.

A DMF layer is extracted from the phase separation layer, and then, three times vortexed with 2 mL of octane. If necessary, filtering may be performed to remove any floating matter. Finally, a mixed solvent of DMF and toluene in a ratio of 1:2 is added thereto, and then centrifuged at 6,000 rpm for 5 minutes to precipitate and separate the quantum dots.

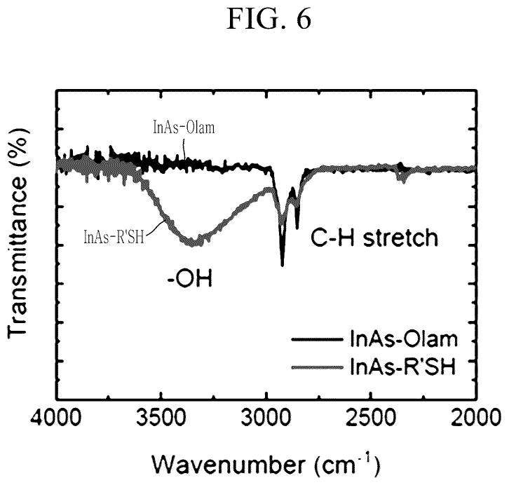

FIG. 6 is a Fourier transform infrared (FTIR) measurement graph for the quantum dots of Reference Example 1 and Example 1. Referring to FIG. 6, the quantum dots (InAs-Olam) of Reference Example 1 are surface-passivated by oleylamine, from which only stretching (C—H stretching) between carbon and hydrogen of an alkyl group is observed, but quantum dots of Example 1 in which oleylamine is substituted with MPD (InAs-R′SH) exhibits a characteristic peak due to a hydroxy group (—OH) of glycerol. Accordingly, the surface ligand of the quantum dots of Reference Example 1 is confirmed to be effectively substituted with MPD.

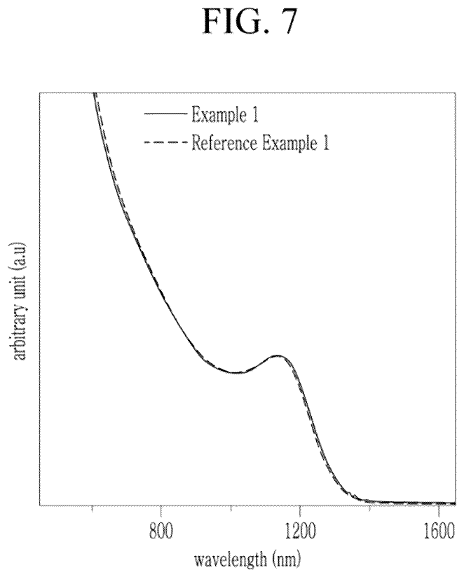

FIG. 7 is a Vis-IR absorption spectrum graph of the quantum dots of Reference Example 1 and Example 1. Referring to FIG. 7, two types of the quantum dots before and after modifying a ligand on the surface of the quantum dots exhibit completely identical Vis-IR absorption spectra, which all have the same absorption peak wavelength at about 1100 nm.

### Example 2: Preparation of InAs Quantum Dots Surface-Modified with Mercaptoethanol (ME)

The quantum dots of Preparation Example 1 are surface-modified with mercaptoethanol (ME) in a similar method to Example 1. In other words, quantum dots passivated with ME (InAs-ME) on the surface of the InAs quantum dots are prepared in the same manner as in Example 1 except that ME is used instead of MPD as a surface modifying compound.

### Experimental Example 1: Fabrication of Field Effect Transistors (FETs) and Measurement of FET Mobility

The quantum dots according to Reference Example 1 and Examples 1 and 2 are respectively used to manufacture FETs, which are measured with respect to field effect mobility, and the results are shown in Table 1.

The FET devices are manufactured to have the same structure as shown in FIG. 1, and a semiconductor layer of each device is formed respectively by using the quantum dots of Reference Example 1 and Examples 1 and 2.

Specifically, a doped Si substrate having a SiO2 gate oxide of a predetermined thickness is prepared, and each quantum dot solution of Reference Example 1 and Examples 1 and 2 is coated on the substrate to form the semiconductor layer. Subsequently, indium (In) and gold (Au) contacts are deposited on the substrate, which are respectively used as a source electrode and a drain electrode.

The devices are manufactured under a dry nitrogen atmosphere, and the quantum dot solution is dried at a predetermined temperature to dry the solvent therefrom to form the semiconductor layer.

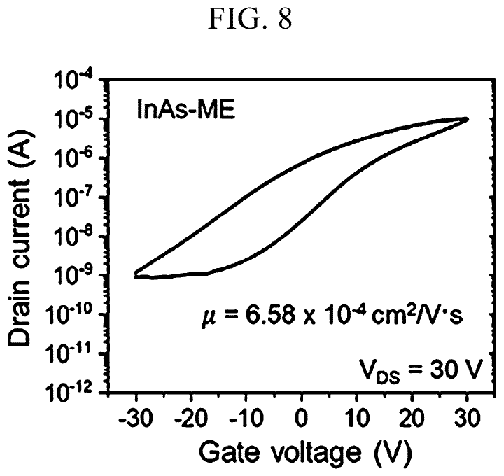

The manufactured devices are measured with respect to electrical properties, and the results are shown in Table 1 and FIG. 8. FIG. 8 shows the drain current (source-drain current versus gate voltage: IDS-VG) properties of the FET device including the quantum dots (InAs-ME) according to Example 2 as a semiconductor layer. Referring to FIG. 8, the device including the quantum dots (InAs-ME) of Example 2 as the semiconductor layer is confirmed to have an electric flow. The device is confirmed to exhibit electron mobility of 6.58×10⁻⁴ cm²/ Vs, which is calculated from an IDS-VG curve of FIG. 8. This is a very high FET mobility level. The device including the quantum dots (InAs-R′SH) of Example 1 as a semiconductor layer is also calculated with respect to mobility in the same manner as above, and the result is shown Table 1.

TABLE 1

| | Mobility (cm²/Vs) |
|---|---|
| Reference Example 1 | — |
| Example 1 | 2.59 E−4 |
| Example 2 | 6.58 E−4 |

Referring to Table 1, FET including the quantum dots surface-modified with ME (InAs-ME) according to Example 2 as a semiconductor layer exhibits more excellent mobility than FET including the quantum dots surface-modified with MPD (InAs-R′SH) according to Example 1 as a semiconductor layer. Although not intended to be bound by a specific theory, this result, as described above, is thought to obtain faster charge mobility, because the carbon number of the ligand (ME) bound to the surface of the quantum dots according to Example 2 is smaller than that of the ligand (MPD) bound to the surface of the quantum dots according to Example 1.

On the contrary, the quantum dots of Reference Example 1 passivated with oleylamine are almost insulators, whose mobility is immeasurable.

### Experimental Example 2: Preparing and Characterization of Heterojunction Photodiode

MoO₃ is deposited on an ITO substrate, and then, each dispersion of the quantum dots of Reference Example 1 and Example 1 is spin-coated thereon to form a semiconductor layer. On the semiconductor layer, an ETL material such as TiO₂ and the like is spin-coated, and then, aluminum is deposited thereon to form an electrode (contact).

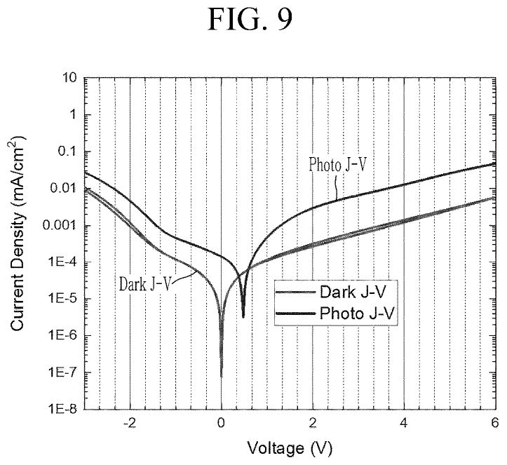

Among diodes manufactured as described above, for the diode including the quantum dots passivated with oleylamine as a semiconductor layer according to Reference Example 1, the current density results of one case of applying a voltage alone to both electrodes without applying light (Dark J-V of FIG. 9) and the other case of applying the voltage through an ITO electrode, while applying visible-IR light (Photo J-V of FIG. 9) are shown in FIG. 9. Referring to FIG. 9, because the semiconductor layer including the quantum dots of Reference Example 1 absorbs the applied visible-IR light and converts it into an electrical signal (Photo J-V of FIG. 9), the current density is confirmed to be improved, compared with the case of not applying the visible-IR ray (Dark J-V of FIG. 9).

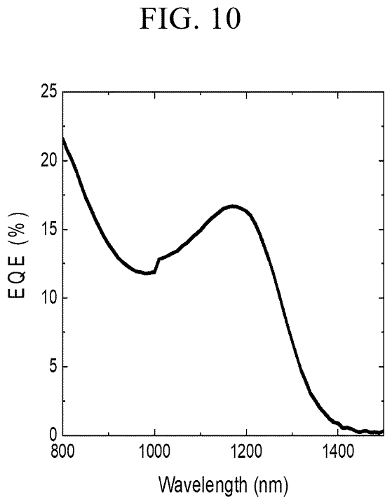

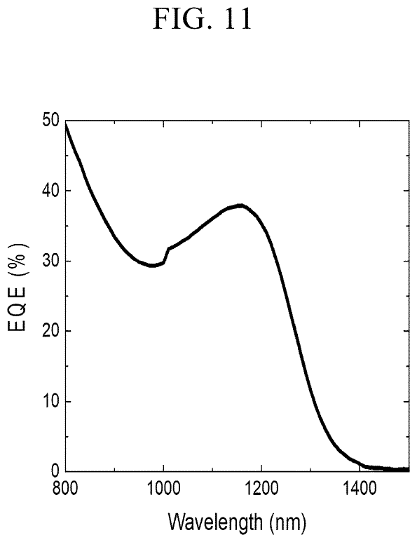

In addition, the manufactured devices are measured with respect to EQE, and the results are shown in FIGS. 10 and 11.

FIG. 10 shows the EQE measurement results of the device including the quantum dots of Preparation Example 1 in a semiconductor layer, and FIG. 11 shows the EQE measurement results of the device including the quantum dots of Example 1 in a semiconductor layer.

The device including the quantum dots of Reference Example 1 in the semiconductor layer exhibits EQE of about 15% at around 1,200 nm, but the device including the quantum dots of Example 1 in the semiconductor layer exhibits very high EQE of about 35% at the same wavelength.

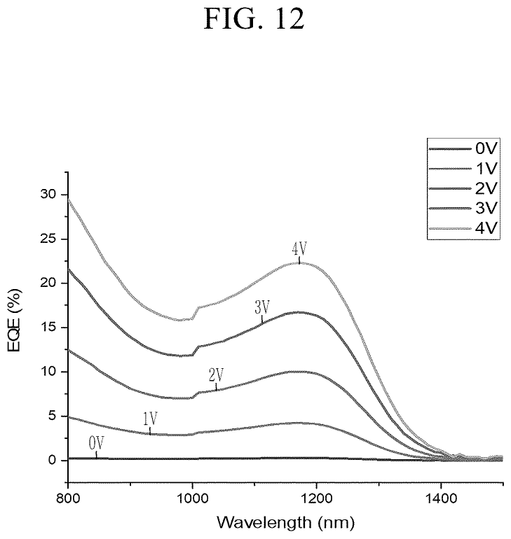

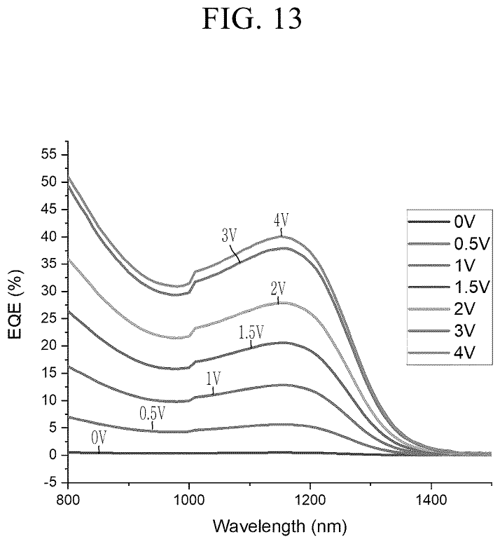

In addition, EQE is measured while the voltage applied to the devices is gradually increased, and the results are respectively shown FIGS. 12 and 13. FIG. 12 shows the results for the device including the quantum dots of Reference Example 1 in a semiconductor layer, and FIG. 13 shows the results for the device including the quantum dots of Example 1 in a semiconductor layer. Referring to FIGS. 12 and 13, both of the devices exhibit increased EQE, as the voltage is increased, but similar to the results of FIGS. 10 and 11, the device including the quantum dots of Example 1 (FIG. 13) exhibits much higher EQE within all the voltage ranges than the device including the quantum dots according to Reference Example 1 (FIG. 12).

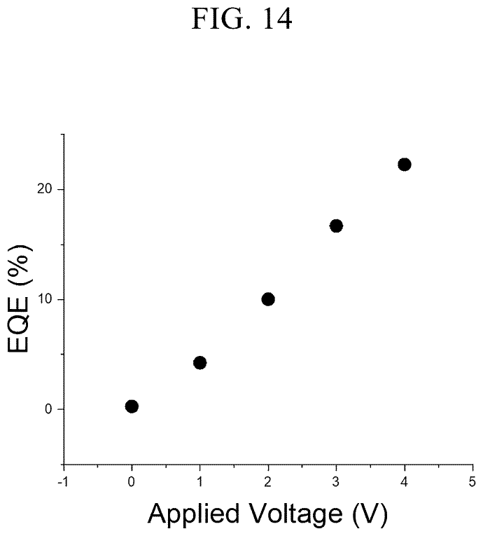

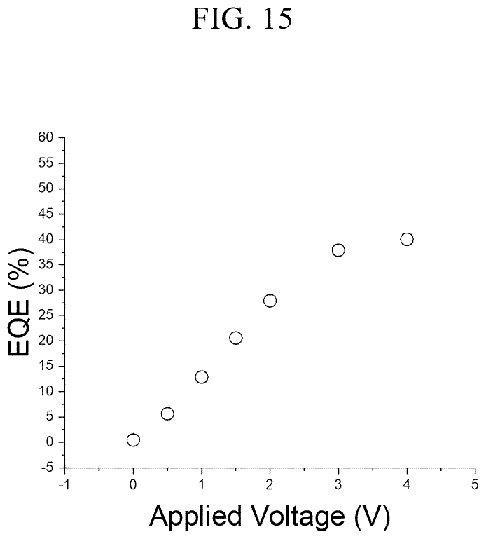

FIGS. 14 and 15 are graphs showing the EQE increase pattern with respect to the applied voltage. FIG. 14 shows the results for the device including the quantum dots of Reference Example 1, and FIG. 15 shows the results for the device including the quantum dots of Example 1. Referring to FIG. 14, the device including the quantum dots of Reference Example 1 is expected to exhibit EQE near to 20%, when the voltage is increased to about 4 V, but the device actually fails in withstanding a voltage of 4 V or higher and is broken. On the other hand, as shown in the graph of FIG. 15, the device including the quantum dots of Example 1 exhibits EQE increased to about 40%, when the voltage is about 3 V, and even if the voltage is greater than 4 V, the device is not broken but maintained at EQE of about 40% in a saturated state.

In conclusion, the device including the surface-modified quantum dots according to an embodiment, compared with the device including the quantum dots before the surface modification, exhibits much excellent stability and electrical characteristics such as charge mobility, EQE, and the like.

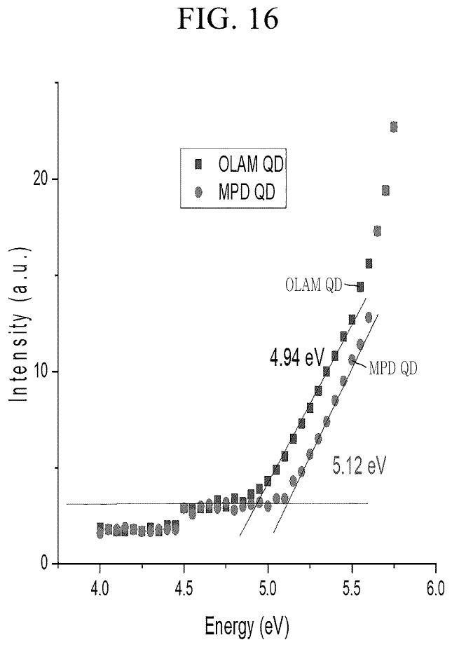

FIG. 16 is a graph showing intensity of photoelectrons generated from each thin film with respect to energy applied to the thin film, which is respectively a thin film (OLAM QD) including the quantum dots of Reference Example 1 and a thin film (MPD QD) including the quantum dots of Example 1. The Intensity of generated photoelectrons may be used to measure a work function and a HOMO (highest occupied molecular orbital) level of each of the quantum dots. Referring to FIG. 16, the ligand (oleylamine) of the quantum dots (OLAM QD) of Reference Example 1 is substituted with MPD in Example 1, so that the quantum dots (MPD QD) may have a deeper HOMO level. Accordingly, it is predicted to extract holes from the photodiode including the quantum dots of Example 1 more easily. In addition, referring to FIG. 16, the ligand (oleylamine) of the quantum dots (OLAM QD) of Reference Example 1 is confirmed to be substituted with MPD in Example 1 (i.e., form MPD QD).

While this invention has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A quantum dot, comprising a Group IIIA element and a Group VA element of the periodic table of elements, wherein the quantum dot has an absorption peak wavelength of greater than or equal to about 1,000 nanometers in a visible-infrared absorption spectrum, and comprises a ligand derived from an aliphatic hydrocarbon compound substituted with a hydroxyl group and a thiol group on a surface of the quantum dot.

2. The quantum dot of claim 1, wherein the quantum dot does not comprise mercury, cadmium, lead, or a combination thereof.

3. The quantum dot of claim 1, wherein the quantum dot has an average particle size of greater than or equal to about 2.5 nanometers.

4. The quantum dot of claim 1, wherein the Group IIIA element comprises indium, aluminum, gallium, or a combination thereof.

5. The quantum dot of claim 1, wherein the Group VA element comprises arsenic, antimony, bismuth, or a combination thereof.

6. The quantum dot of claim 1, wherein the ligand is derived from a linear or branched aliphatic hydrocarbon compound having 2 to 30 carbon atoms substituted with one or more hydroxyl groups and one or more thiol groups.

7. The quantum dot of claim 1, wherein the aliphatic hydrocarbon compound substituted with a hydroxyl group and a thiol group comprises 1-hydroxy-2-mercapto ethane, 1,2-dihydroxy-3-mercapto propane, or a combination thereof.

8. The quantum dot of claim 1, wherein the absorption peak wavelength of the quantum dot is in a range of about 1,000 nanometers to about 1,800 nanometers.

9. The quantum dot of claim 1, wherein the quantum dot comprises indium and arsenic.

10. The quantum dot of claim 1, wherein a molar ratio of the Group VA element to the Group IIIA element in the quantum dot is greater than or equal to about 0.5:1 and less than or equal to about 1:1.

11. An electronic device, comprising
a first electrode and a second electrode spaced apart from each other, and
a semiconductor layer comprising a quantum dot between the first electrode and the second electrode,
wherein the semiconductor layer comprises the quantum dot of claim 1.

12. The electronic device of claim 11, wherein the first electrode and the second electrode have main surfaces facing each other, and the semiconductor layer is interposed between the first electrode and the second electrode.

13. The electronic device of claim 11, wherein the electronic device further comprises a charge auxiliary layer between the semiconductor layer and the first electrode, between the semiconductor layer and the second electrode, or both.

14. The electronic device of claim 11, wherein the device further comprises a third electrode facing the semiconductor layer; and an insulating layer between the semiconductor layer and the third electrode.

15. The electronic device of claim 11, wherein the electronic device has a field effect mobility of greater than or equal to about 10⁻⁵ square centimeters per vol-second.

16. The electronic device of claim 11, wherein the electronic device has an external quantum efficiency of greater than or equal to about 10%.

17. A method for preparing a quantum dot, comprising
preparing a precursor solution of a Group IIIA element comprising a precursor of a Group IIIA element, a first amine compound, and optionally a phosphine compound;
preparing a precursor solution of a Group VA element comprising a precursor of a Group VA element and a second amine compound;
while heating the precursor solution of the Group IIIA element, mixing the precursor solution of the Group VA element with the precursor solution of the Group IIIA element to react the precursor of the Group IIIA element and the precursor of the Group VA element;
after the reacting, obtaining a quantum dot comprising the Group IIIA element and the Group VA element, and comprising the first amine compound, the second amine compound, the optional phosphine compound, or a combination thereof on a surface of the quantum dot; and
replacing the first amine compound, the second amine compound, the phosphine compound, or the combination thereof on the surface of the obtained quantum dot with an aliphatic hydrocarbon compound substituted with a hydroxy group and a thiol group,
wherein the quantum dot comprises the Group IIIA element and the Group VA element, and has an absorption peak wavelength of greater than or equal to about 1,000 nanometers in a visible-infrared absorption spectrum.

18. The method of claim 17, wherein the precursor of the Group IIIA element and the precursor of the Group VA element comprise a halide, a sulfide, an amine compound of the Group IIIA element and the Group VA element, or a combination thereof.

19. The method of claim 17, wherein the first amine compound and the second amine compound are the same or different and are each independently RNH₂, R₂NH, or a combination thereof, wherein R each independently represents a C5 to C40 substituted or unsubstituted aliphatic hydrocarbon group, a C6 to C40 substituted or unsubstituted aromatic hydrocarbon group, or a combination thereof.

20. The method of claim 17, wherein the phosphine compound is present, and comprises R₃PO, R₂HPO, RH₂PO, R₃P, R₂PH, RPH₂, RPO(OH)₂, RHPOOH, R₂POOH, or a combination thereof, wherein R each independently represents a C5 to C40 substituted or unsubstituted aliphatic hydrocarbon group, a C₆ to C₄₀ substituted or unsubstituted aromatic hydrocarbon group, or a combination thereof.
